(19) United States
(12) Patent Application Publication
(10) Pub. No.: US 2026/0017441 A1
(43) Pub. Date: Jan. 15, 2026

(54) SEMICONDUCTOR INTEGRATED CIRCUIT DESIGN ASSISTANCE METHOD

(71) Applicant: Socionext Inc., Kanagawa (JP)

(72) Inventor: Yukihiro SASAGAWA, Yokohama (JP)

(21) Appl. No.: 19/332,239

(22) Filed: Sep. 18, 2025

Related U.S. Application Data
(63) Continuation of application No. PCT/JP2023/014122, filed on Apr. 5, 2023.

(51) Int. Cl. G06F 30/327; G06F 30/392; G06N 3/042; G06N 3/08

(52) U.S. Cl. CPC G06F 30/327; G06F 30/392; G06N 3/042; G06N 3/08

(57) ABSTRACT

A semiconductor integrated circuit design assistance method includes: converting a hardware description into a graph object; inferring an inferred physical metric of a semiconductor integrated circuit by inputting the graph object into a neural network trained in a GAT method; and extracting an attention part of the hardware description based on the inferred physical metric. The graph object includes a node and an edge. The node includes a first node including description position information that indicates a position in the hardware description. The neural network includes, as a weight, an attention coefficient that indicates a degree of influence that the edge has on the inferred physical metric. In the extracting, a first edge is identified based on the attention coefficient, and a part of the hardware description is extracted as the attention part based on the description position information of the first node that corresponds to the first edge.

### CROSS REFERENCE TO RELATED APPLICATION(S)

This is a continuation application of PCT Patent Application No. PCT/JP2023/014122 filed on Apr. 5, 2023, designating the United States of America. The entire disclosure of the above-identified application, including the specification, drawings and claims is incorporated herein by reference in its entirety.

### FIELD

The present disclosure relates to a semiconductor integrated circuit design assistance method.

### BACKGROUND

A method of designing a semiconductor integrated circuit has been conventionally considered. A process for generating information that is necessary for designing and manufacturing a semiconductor integrated circuit includes multiple stages from an initial stage, such as determination of an operation specification represented by a hardware description written in a hardware description language, to a final stage, such as a layout of wiring and constituent elements of the semiconductor integrated circuit (for example, see Patent Literature (PTL) 1) PTL 1 discloses a concept for inferring, at the initial stage of the design of the semiconductor integrated circuit, a quality metric of the semiconductor integrated circuit to be manufactured based on the design. Thus, a time required for design is attempted to be shortened by providing feedback for improving the quality metric of the design without performing all stages of the design.

### CITATION LIST

### Patent Literature

PTL1: United States Patent Application Publication No. 2021/0287120

### Non Patent Literature

NPL1: Petar Velickovic, et.al., “Graph Attention Networks”, ICLR, 2018

### SUMMARY

### Technical Problem

However, PTL 1 does not disclose a specific method for providing feedback on the design. Therefore, even if a quality metric can be inferred, it is not possible to estimate on which statement in a hardware description, which is written in a hardware description language, feedback should be provided, for example.

Then, the present disclosure provides a semiconductor integrated circuit design assistance method in which, based on a hardware description in which a semiconductor integrated circuit is described, a physical metric of the semiconductor integrated circuit can be estimated with high accuracy and the position, in the hardware description, of a statement having a big influence on the physical metric can be identified.

### Solution to Problem

A semiconductor integrated circuit design assistance method according to an aspect of the present disclosure includes: converting, into a graph object in a control data flow graph (CDFG) format, a hardware description in which a semiconductor integrated circuit is described in a hardware description language; inferring an inferred physical metric of the semiconductor integrated circuit by inputting the graph object into a neural network that has been trained and is represented by a graph attention network (GAT) method; and extracting an attention part of the hardware description based on the inferred physical metric. In the semiconductor integrated circuit design assistance method, the graph object includes a plurality of nodes and one or more edges that have been converted from one or more statements in the hardware description, the plurality of nodes include one or more first nodes in each of which description position information that indicates a position in the hardware description is embedded, each of the one or more first nodes is related to, among the one or more statements in the hardware description, one or more statements that are indicated by the description position information of the first node, the neural network includes, as one or more weights, one or more attention coefficients each of which indicates a degree of influence that a different one of the one or more edges has on the inferred physical metric, and in the extracting, one or more first edges are identified from among the one or more edges based on the one or more attention coefficients and a part of the hardware description is extracted as the attention part based on the description position information of, among the one or more first nodes, each pair of first nodes that corresponds to a different one of the one or more first edges.

### Advantageous Effects

The present disclosure provides a semiconductor integrated circuit design assistance method in which, based on a hardware description in which a semiconductor integrated circuit is described, a physical metric of the semiconductor integrated circuit can be estimated with high accuracy and the position, in the hardware description, of a statement having a big influence on the physical metric can be identified.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating the outline of a functional configuration of a semiconductor integrated circuit design assistance device according to an embodiment.

FIG. 2 is a block diagram illustrating the outline of a functional configuration of a preparation unit according to the embodiment.

FIG. 3 is a block diagram illustrating the outline of a functional configuration of an estimator according to the embodiment.

FIG. 4 illustrates an example of a hardware description.

FIG. 5 illustrates an example of a training graph object according to the embodiment.

FIG. 6 illustrates an example of a hardware configuration of a computer that realizes, by using software, a function of the semiconductor integrated circuit design assistance device according to the embodiment.

FIG. 7 is a flowchart indicating a flow of a semiconductor integrated circuit design assistance method according to the embodiment.

FIG. 8 is a flowchart indicating a flow of a preparation step of the semiconductor integrated circuit design assistance method according to the embodiment.

FIG. 9 is a flowchart indicating a flow of a derivation step of the semiconductor integrated circuit design assistance method according to the embodiment.

### DESCRIPTION OF EMBODIMENT

Hereinafter, an embodiment of the present disclosure will be described in detail with reference to the Drawings. It should be noted that the embodiment described below shows a specific example of the present disclosure. The numerical values, shapes, materials, standards, constituent elements, the arrangement and connection of the constituent elements, steps, the processing order of the steps, etc. shown in the following embodiment are mere examples, and do not limit the scope of the present disclosure. Moreover, among the constituent elements in the following embodiment, those not recited in the independent claim defining the broadest concept of the present disclosure are described as arbitrary constituent elements. Furthermore, respective drawings are not necessarily precise illustrations. In the Drawings, components that are essentially the same share like reference signs and overlapping explanations thereof may be omitted or simplified.

### EMBODIMENT

A semiconductor integrated circuit design assistance method and a semiconductor integrated circuit design assistance device according to the embodiment will be described.

### [1. Semiconductor Integrated Circuit Design Assistance Device]

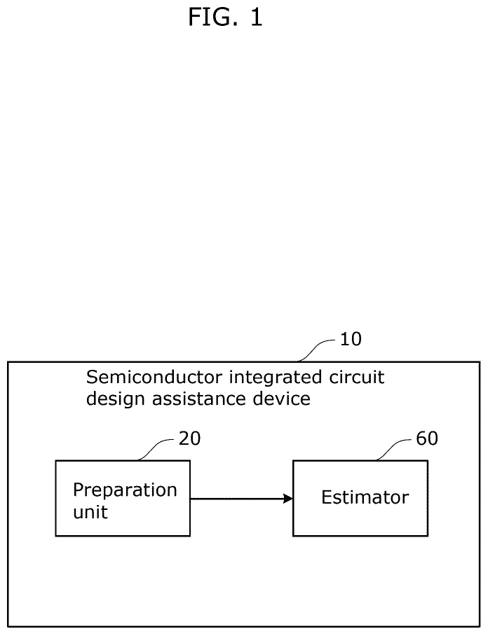

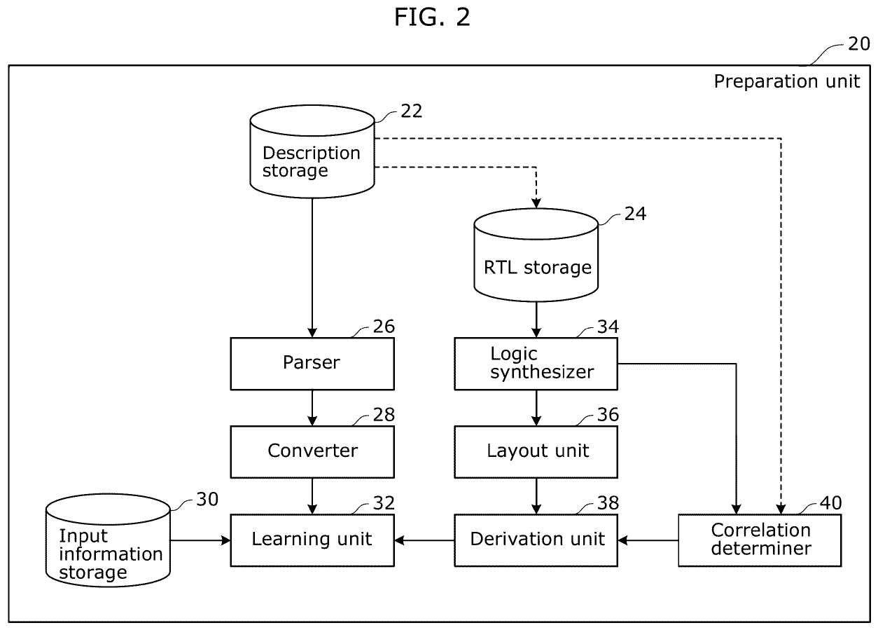

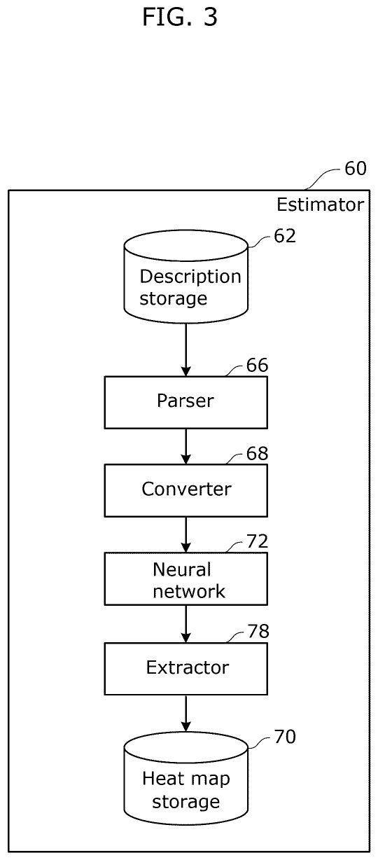

A configuration of a semiconductor integrated circuit design assistance device according to the present embodiment will be described with reference to FIG. 1 to FIG. 3. FIG. 1 is a block diagram illustrating the outline of a functional configuration of semiconductor integrated circuit design assistance device 10 according to the present embodiment. FIG. 2 is a block diagram illustrating the outline of a functional configuration of preparation unit 20 according to the present embodiment. FIG. 3 is a block diagram illustrating the outline of a functional configuration of estimator 60 according to the present embodiment.

Semiconductor integrated circuit design assistance device 10 is a device that assists in providing feedback on a hardware description by estimating, based on the hardware description, a physical metric of a semiconductor integrated circuit designed based on the hardware description and extracting, from the hardware description, an attention part having a high degree of influence on the physical metric. The hardware description is a description in which the semiconductor integrated circuit is described in a hardware description language. A specification, such as a configuration and operation of the semiconductor integrated circuit, is described in the hardware description. The hardware description language in which the hardware description is written is not particularly limited. For example, the hardware description may be written at a register transfer level (RTL), at a behavioral level, or in a unified modeling language (UML).

Here, the physical metric is an indicator based on a physical concept of the semiconductor integrated circuit. For example, the physical metric includes: a degree of wire congestion that indicates a total number of wires present in a unit region in layout data of the semiconductor integrated circuit; a power density that indicates power consumed in a unit region in the layout data of the semiconductor integrated circuit; or the like.

As illustrated in FIG. 1, semiconductor integrated circuit design assistance device 10 includes preparation unit 20 and estimator 60.

Preparation unit 20 is a processing unit that prepares a neural network that has been trained by a graph attention network (GAT) method. As illustrated in FIG. 2, preparation unit 20 includes description storage 22, RTL storage 24, parser 26, converter 28, input information storage 30, learning unit 32, logic synthesizer 34, layout unit 36, derivation unit 38, and correlation determiner 40.

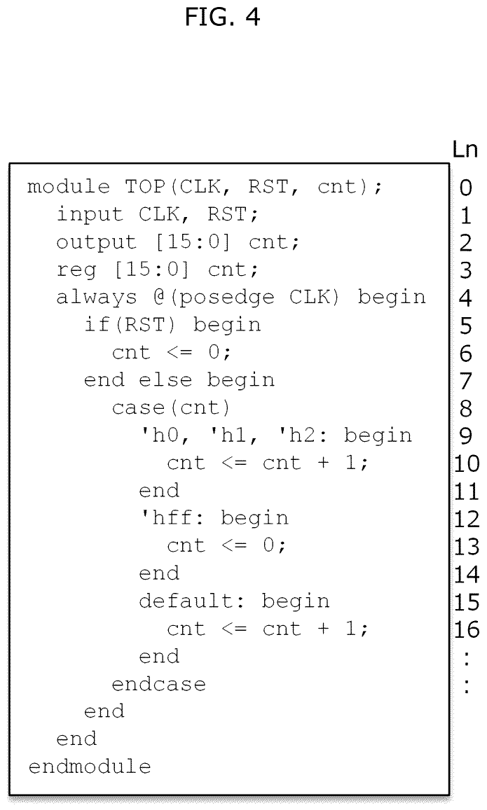

Description storage 22 is an example of a training description storage that stores a training hardware description used for training a neural network. A training semiconductor integrated circuit is described in the training hardware description. Description storage 22 stores one or more training hardware descriptions. Here, a hardware description will be described with reference to FIG. 4. FIG. 4 illustrates an example of a hardware description. As illustrated in FIG. 4, a hardware description is a code written in a hardware description language. FIG. 4 also shows Line numbers Ln in the hardware description.

RTL storage 24 stores a hardware description that is written at an RTL and corresponds to the training hardware description stored in description storage 22. It should be noted that the training hardware description stored in description storage 22 may be a hardware description written at an RTL, similar to the hardware description stored in RTL storage 24. In other words, description storage 22 may store the same training hardware description as RTL storage 24. In this case, description storage 22 may also serve as RTL storage 24.

Parser 26 is a processing unit that performs syntax analysis on the training hardware description stored in description storage 22.

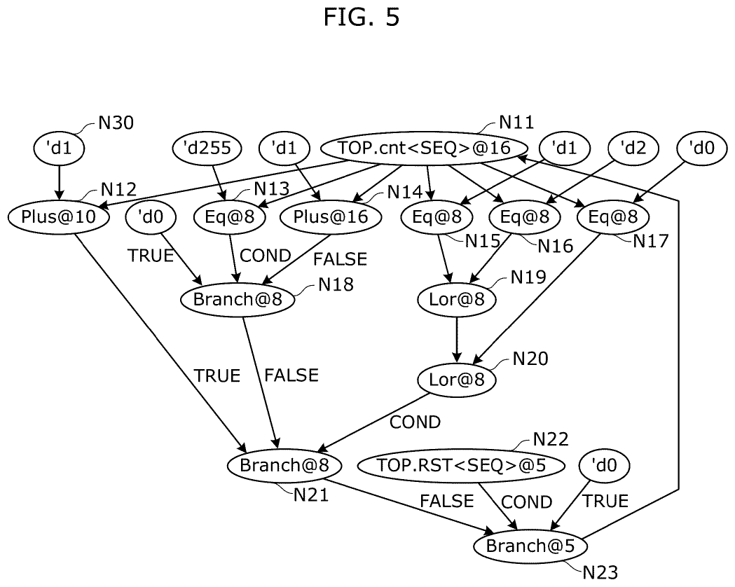

Converter 28 is a processing unit that converts the training hardware description into a training graph object in a control data flow graph (CDFG) format and is an example of a training converter. In the present embodiment, the training hardware description on which syntax analysis has been performed by parser 26 is converted into a training graph object. Here, a training graph object will be described with reference to FIG. 5. FIG. 5 illustrates an example of a training graph object according to the present embodiment. In FIG. 5, an example of a training graph object corresponding to the hardware description illustrated in FIG. 4 is illustrated. In FIG. 5, an oval represents a node and an arrow represents an edge. The training graph object includes a plurality of nodes and one or more edges that have been converted from one or more statements in the training hardware description. Each of the one or more edges is connected to one node and another node. Each of the plurality of nodes corresponds to any of one or more hardware instances that achieve a function described in the hardware description, and each of the one or more edges corresponds to any of one or more connection parts such as one or more wirings connected to the one or more hardware instance. The one or more hardware instances include, for example, a gate, a register, or the like. Moreover, when the hardware description is written in a unified modeling language, the one or more hardware instances include a unit such as a central processing unit (CPU).

The plurality of nodes include one or more first nodes in each of which description position information that indicates a position, in the training hardware description, of a part corresponding to the first node is embedded. Each of the one or more first nodes is related to, among the one or more statements in the training hardware description, one or more statements indicated by the description position information of the first node. In the present embodiment, line number Ln in the training hardware description is embedded as the description position information in each of the one or more first nodes. In the example illustrated in FIG. 5, node N11 to node N23 are equivalent to the one or more first nodes, and the number after “@” shown in each node is equivalent to line number Ln. Moreover, the one or more first nodes include a second node that corresponds to an operator. Furthermore, the one or more first nodes include node N22 that performs a sequential operation, or the like. In the example illustrated in FIG. 5, each of node N12 and node N14 is equivalent to the second node. In the present embodiment, each of the one or more first edges includes, as a feature, an amount of information transmitted by the connection part corresponding to the first edge. Moreover, the hardware description is written at the RTL, and one or more connection parts corresponding to the one or more first edges are one or more wirings connected to the one or more hardware instances. Each of the one or more wirings includes a bus architecture, and the amount of information transmitted by each of the one or more connection parts corresponding to the one or more first edges includes a bus width of the bus architecture.

It should be noted that each of the one or more first nodes may include, as a feature, a degree of computational complexity in, among the one or more hardware instances, one or more hardware instances corresponding to one or more statements in the hardware description indicated by the description position information. Here, the computational complexity is, for example, computational complexity (order of growth) representing the computational performance of an algorithm. The computational complexity includes concepts such as time complexity (processing time) and space complexity (memory usage). A typical method for representing time complexity is a big O notation. The big O notation includes: O(1) denoting constant time complexity; O(log N) denoting logarithmic time complexity; O(N) denoting linear time complexity; O(N log N) denoting quasilinear time complexity or linearithmic time complexity; O(N\hat{ }2) denoting quadratic time complexity; O(N\hat{ }3) denoting polynomial time complexity; O(k\hat{ }N) denoting exponential time complexity; and O(N!) denoting factorial time complexity, in the ascending order of processing time. Moreover, each of the one or more first nodes may include, as a feature, a total number of inputs to the first node. Furthermore, each of the one or more first edges may include, as a feature, an amount of information transmitted by one or more connection parts corresponding to the first edge. Furthermore, each of the one or more first nodes may include, as a feature, a total number of nodes through which an input passes before reaching the first node among the plurality of nodes. For example, a total number of nodes through which an input passes before reaching node N21 (i.e., a total number of nodes that are connected in series and through which an input passes before reaching node N21) is two, that is, node N30 and node N12 (or node N11 and node N12).

Thus, learning based on more information is made possible by embedding, as a feature, into the neural network, an indicator related to a physical metric of the semiconductor integrated circuit. Accordingly, the accuracy of inference by the neural network can be increased.

Moreover, each of the one or more first nodes may include, as a feature, a degree of computational disadvantage such as a computational cost or computational complexity of the first node that corresponds to an operator. Furthermore, each of the one or more first nodes may include, as a feature, a degree of computational advantage such as a computational efficiency or power efficiency of the first node that corresponds to an operator. Thus, learning based on more information is made possible by embedding, as a feature, into the neural network, an indicator related to a physical metric of the semiconductor integrated circuit. Accordingly, the accuracy of inference by the neural network can be increased. Moreover, by using a degree of computational disadvantage as a feature, the degree of computational disadvantage can be used as a degree of importance of a design problem. Furthermore, by using a degree of computational advantage as a feature, the degree of computational advantage can be used as a degree of importance that is traded off with the degree of disadvantage.

Input information storage 30 stores input information to be inputted into learning unit 32. Input information storage 30 stores, for example, a constraint condition of the training semiconductor integrated circuit, library information such as structure information on the constituent elements included in the training semiconductor integrated circuit, or the like. The library information includes, for example, structure information, circuit information, or the like of each unit that is included as a constituent element of the training semiconductor integrated circuit when the training hardware description is written in a unified modeling language. It should be noted that input information storage 30 is not an essential constituent element.

Learning unit 32 is a processing unit that trains a neural network by using, as an input, the training graph object obtained by conversion by converter 28 and using, as training data, an expected physical metric value derived by derivation unit 38. In learning unit 32, a neural network represented by a graph attention network (GAT) method is trained. The GAT method is a method in which a degree of contribution to inference of each of one or more edges included in a graph object is represented by a weight for a feature (see NPL 1 and so on). The weight is called an attention coefficient. Attention coefficient eᵢⱼ between node i and node j (i.e., an attention coefficient of an edge connecting node i and node j) is defined as shown below.

$$[ Math . 1 ]$$

$${e}_{ij} = a ( W \vec{{h}_{i}} , W \vec{{h}_{j}} ) , \vec{{h}_{i}} ∈ {F}^{} , \vec{{h}_{j}} ∈ {{F}^{′}}^{} , W ∈ {{F}^{′} \times F}^{} , a \text{:} {{F}^{′}}^{} {F}^{} \to$$

$$Here ,$$

$$\vec{{h}_{i}} and \vec{{h}_{j}} \qquad [ Math . 2 ]$$

denote a feature of node i and a feature of node j, respectively. Moreover, F and F′ denote a total number of features in node i and a total number of features in node j, respectively, and W denotes a weight matrix.

Attention coefficient aᵢⱼ obtained by normalizing attention coefficient eᵢⱼ is defined as shown below.

$${α}_{ij} = softmax ( {e}_{ij} ) = \frac{exp ( {e}_{ij} )}{{\sum }_{k ∈ {N}_{i}} exp ( {e}_{ik} )} , j ∈ {N}_{i} \qquad [ Math . 3 ]$$

Here, Nᵢ denotes an index set of one or more nodes each of which is next to node i in the training graph object.

When normalized attention coefficient aᵢⱼ between node i and node j is used, map coefficient mi denoting a degree of importance of node i can be defined as an average value of normalized attention coefficient aᵢⱼ between node i and one or more nodes Ni each of which is next to node i, as shown below.

$${m}_{i} = \frac{{\sum }_{k ∈ {N}_{i}} {α}_{ik}}{number of {N}_{i}} \qquad [ Math . 4 ]$$

By training a neural network in preparation unit 20, a neural network that can predict an attention coefficient that indicates a degree of importance of each edge can be achieved. Accordingly, a degree of importance of each node can be predicted by using map coefficient mi. Since description position information indicating a position in the training hardware description is embedded in each node as described above, a description position in a hardware description and a degree of importance can be associated with each other. In other words, it is possible to predict that a description position in a hardware description indicated by description position information that is embedded in a node of which degree of importance is high (i.e., of which map coefficient mi is high) is a part to be revised (i.e., a feedback target part) for improving the hardware description.

It should be noted that, in addition to the training graph object, other input information such as a constraint condition or library information may be inputted into learning unit 32 from input information storage 30.

Logic synthesizer 34 is a processing unit that generates a gate level netlist based on the training hardware description. In the present embodiment, logic synthesizer 34 generates a gate level netlist by performing logic synthesis on the hardware description written at the RTL stored in RTL storage 24.

Layout unit 36 is a processing unit that generates layout data of a semiconductor integrated circuit based on the gate level netlist generated by logic synthesizer 34. The layout data indicates a layout of each gate, each wiring, or the like included in the semiconductor integrated circuit.

Correlation determiner 40 is a processing unit that determines correlation between each statement in the training hardware description and each gate included in the gate level netlist generated by logic synthesizer 34. For example, correlation determiner 40 determines the correlation by using a fact that an identifier string assigned to each gate included in the gate level netlist is derived from a string representing a variable written in the training hardware description (and the hardware description written at the RTL). Specifically, an expected value of a degree of correlation between each statement in the training hardware description and each gate included in the gate level netlist can be obtained by using a locality sensitive hashing (LSH) function to convert, into features, a string included in each statement in the training hardware description and an identifier string of each gate included in the gate level netlist and obtaining a degree of correlation between the features.

Derivation unit 38 is a processing unit that derives an expected physical metric value from the layout data of the training semiconductor integrated circuit. For example, derivation unit 38 derives, a degree of wire congestion or power density per unit region as an expected physical metric value. In the present embodiment, derivation unit 38 obtains, for each statement in the training hardware description, an expected heat map value indicating a degree of importance of the statement, based on an expected physical metric value and an expected correlation value obtained by correlation determiner 40.

Estimator 60 illustrated in FIG. 1 is a processing unit that estimates a part of a hardware description as an attention part having a high degree of influence on a semiconductor integrated circuit, by using the neural network that has been trained and prepared by preparation unit 20. As illustrated in FIG. 3, estimator 60 includes description storage 62, parser 66, converter 68, neural network 72, extractor 78, and heat map storage 70.

Description storage 62 stores a hardware description in which a semiconductor integrated circuit that is a design target is described. Similar to those stored in description storage 22 of preparation unit 20, the hardware description stored in description storage 62 is also a code written in a hardware description language as shown in FIG. 4. For example, the hardware description may be written at an RTL, at a behavioral level, or in a unified modeling language.

Parser 66 is a processing unit that performs syntax analysis on the hardware description stored in description storage 62. Parser 66 has the same configuration as parser 26 of preparation unit 20. It should be noted that parser 26 may also serve as parser 66.

Converter 68 is a processing unit that converts the hardware description into a graph object in a CDFG format, and has the same configuration as converter 28 of preparation unit 20. It should be noted that converter 28 may also serve as converter 68. The graph object has the same configuration as the training graph object obtained by conversion by converter 28 of preparation unit 20. The graph object includes a plurality of nodes and one or more edges that have been converted from one or more statements in the hardware description. Each of the plurality of nodes corresponds to any of one or more hardware instances that achieve a function described in the hardware description, and each of the one or more edges corresponds to any of one or more connection parts such as one or more signal lines connected to the one or more hardware instances. In the present embodiment, each of the one or more edges includes, as a feature, an amount of information transmitted by one or more connection parts corresponding to the edge. Moreover, the hardware description is written at an RTL, and the one or more connection parts corresponding to the one or more edges are one or more wirings connected to the one or more hardware instances. Each of the one or more wirings includes a bus architecture, and the amount of information transmitted by each of the one or more connection parts corresponding to the one or more edges includes a bus width of the bus architecture. For example, an amount of information transmitted by each of an edge connecting node N30 and node N12 and an edge connecting node N11 and node N12 of the graph object illustrated in FIG. 5 may be 8 bit. In this case, an amount of information transmitted by an edge connecting node N12 and node N21 may be 16 bit.

The plurality of nodes include one or more first nodes in each of which description position information indicating a position in the hardware description is embedded. Each of the one or more first nodes is related to, among the one or more statements in the hardware description, one or more statements indicated by the description position information of the first node. The one or more first nodes include a second node that corresponds to an operator. The description position information of the second node includes a first line number that is a number assigned to a line in which the operator is written in the hardware description. The second node includes the first line number as a feature. It should be noted that the second node may include, as a feature, a second line number that is a number assigned to a line in which a variable that is referred to by the operator is defined in the hardware description. Accordingly, the number assigned to the line in which the variable that is referred to by the operator is written in the hardware description can be easily extracted.

Neural network 72 is a neural network that has been trained and is represented by a GAT method. Neural network 72 is the neural network that has been trained in preparation unit 20. The graph object obtained by conversion by converter 68 is inputted into neural network 72, and neural network 72 infers an inferred physical metric of the semiconductor integrated circuit. As described above, neural network 72 that has been trained by preparation unit 20 includes, as one or more weights, one or more attention coefficients each of which indicates a degree of influence that a different one of the one or more edges has on the inferred physical metric.

For example, the inferred physical metric may include a result of inferring a degree of wire congestion indicating a total number of wires present in a unit region in layout data, which has been derived based on the hardware description, of the semiconductor integrated circuit, and may be inferred as a predicted congestion value included in each of the plurality of nodes. Accordingly, the degree of wire congestion can be improved by revising an attention part of the hardware description based on the degree of wire congestion.

Moreover, the inferred physical metric may include a result of inferring a power density indicating power consumed in a unit region in the layout data, which has been derived based on the hardware description, of the semiconductor integrated circuit, and may be inferred as a predicted power density value included in each of the plurality of nodes. Accordingly, the power density can be improved by revising an attention part of the hardware description based on the power density.

Moreover, the inferred physical metric may include a result of inferring a signal propagation time in each of a plurality of signal paths included in the layout data, which has been derived based on the hardware description, of the semiconductor integrated circuit, and may be inferred as a predicted signal propagation time value of, among the plurality of signal paths, each of one or more signal paths that includes any of the plurality of nodes. Accordingly, a critical path that is, among a plurality of signal paths each leading to one node, a signal path through which a signal reaches the one node at a latest timing can be inferred.

Extractor 78 is a processing unit that extracts an attention part of the hardware description based on the inferred physical metric inferred by neural network 72. Extractor 78 identifies one or more first edges from among the one or more edges included in the graph object based on the one or more attention coefficients, and extracts, as an attention part, a part of the hardware description based on information indicating a description position of each of, among the one or more first nodes, one or more first nodes corresponding to the one or more first edges.

Heat map storage 70 stores a heat map that includes the attention part of the hardware description extracted by extractor 78. The heat map is, for example, a hardware description in which a statement having a high degree of importance in the hardware description is indicated by differentiating the color of letters in the attention part according to the degree of importance or attaching a mark to the statement having a high degree of importance.

### [2. Hardware Configuration]

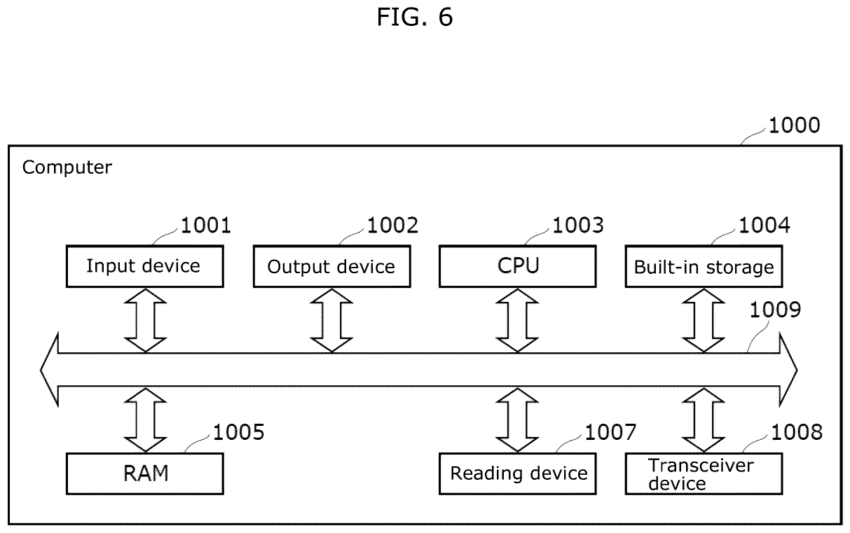

Next, a hardware configuration of semiconductor integrated circuit design assistance device 10 according to the present embodiment will be described with reference to FIG. 6. FIG. 6 illustrates an example of a hardware configuration of computer 1000 that realizes, by using software, a function of semiconductor integrated circuit design assistance device 10 according to the present embodiment.

As illustrated in FIG. 6, computer 1000 includes input device 1001, output device 1002, CPU 1003, built-in storage 1004, RAM 1005, reading device 1007, transceiver device 1008, and bus 1009. Input device 1001, output device 1002, CPU 1003, built-in storage 1004, RAM 1005, reading device 1007, and transceiver device 1008 are connected by bus 1009.

Input device 1001 is a device that serves as a user interface such as an input button, a touch pad, or a touch panel display, and is operated by a user. It should be noted that input device 1001 may be configured to be remotely operated by voice, a remote controller, or the like, other than being operated by touch.

Output device 1002 is a device that outputs a signal from computer 1000, and may be a device that serves as a user interface such a display or a loudspeaker, other than a signal output terminal.

Built-in storage 1004 is a flash memory or the like. Moreover, built-in storage 1004 may store, in advance, at least one of a program for realizing a function of semiconductor integrated circuit design assistance device 10 or an application that uses a functional configuration of semiconductor integrated circuit design assistance device 10, other than data stored in each storage of semiconductor integrated circuit design assistance device 10.

RAM 1005 is a random access memory (RAM) and used for storing data or the like in execution of a program or an application.

Reading device 1007 reads out information from a recording medium such as a universal serial bus (USB) memory. Reading device 1007 reads out the above-described program or application from a recording medium in which the above-described program or application is stored, and causes built-in storage 1004 to store the above-described program or application.

Transceiver device 1008 is a communication circuit for performing wireless or wired communication. For example, transceiver device 1008 may perform communication with a server device connected to a network, download the above-described program or application from the server device, and cause built-in storage 1004 to store the above-described program or application.

CPU 1003 is a central processing unit that copies the program, application, or the like stored in built-in storage 1004, stores the copy of the program, application, or the like in RAM 1005, and sequentially reads out and executes commands included in the copy of the program, application, or the like in RAM 1005.

### [3. Semiconductor Integrated Circuit Design Assistance Method]

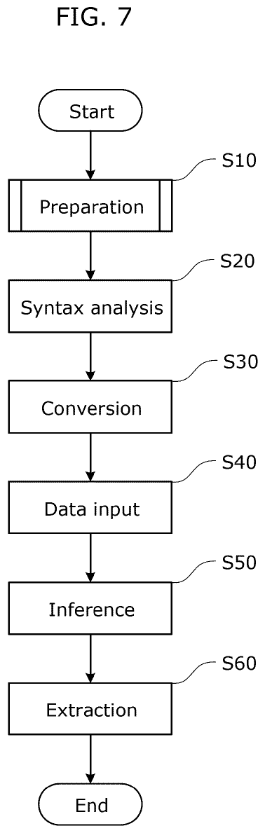

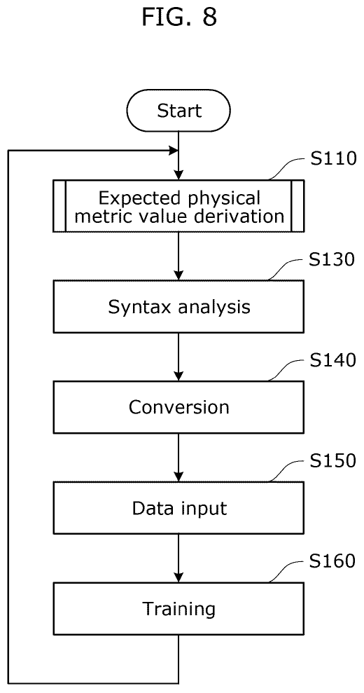

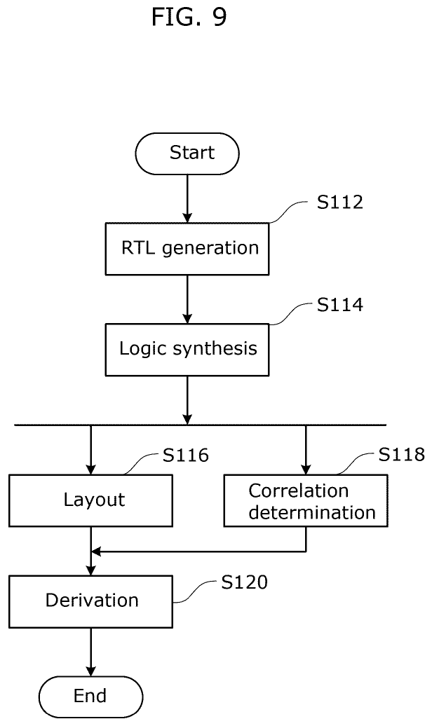

A semiconductor integrated circuit design assistance method according to the present embodiment will be described with reference to FIG. 7 to FIG. 9. FIG. 7 is a flowchart indicating a flow of the semiconductor integrated circuit design assistance method according to the present embodiment. FIG. 8 is a flowchart indicating a flow of a preparation step of the semiconductor integrated circuit design assistance method according to the present embodiment. FIG. 9 is a flowchart indicating a flow of a derivation step of the semiconductor integrated circuit design assistance method according to the present embodiment.

The semiconductor integrated circuit design assistance method according to the present embodiment is a method of assisting in providing feedback on a hardware description by estimating, based on the hardware description, a physical metric of a semiconductor integrated circuit designed based on the hardware description and extracting an attention part having a high degree of influence on the physical metric from the hardware description.

First, as illustrated in FIG. 7, a trained neural network is prepared (preparation step S10). As illustrated in FIG. 8, in preparation step S10, an expected physical metric value of a training semiconductor integrated circuit designed based on a training hardware description written in a hardware description language is derived (expected physical metric value derivation step S110).

As illustrated in FIG. 9, in expected physical metric value derivation step S110, a hardware description written at an RTL corresponding to the training hardware description is generated (RTL generation step S112).

Next, logic synthesis is performed based on the hardware description written at the RTL to generate a gate level netlist (logic synthesis step S114).

Next, layout data is generated based on the gate level netlist (layout step S116). Moreover, correlation between each statement in the training hardware description and each gate included in the gate level netlist generated by logic synthesizer 34 is determined based on the training hardware description and the gate level netlist (correlation determination step S118).

Next, an expected physical metric value is derived from the layout data, which has been generated in layout step S116, of the training semiconductor integrated circuit (derivation step S120). In the present embodiment, in derivation step S120, for each statement in the training hardware description, an expected heat map value indicating a degree of importance of the statement is obtained from the expected physical metric value and an expected correlation value obtained by correlation determiner 40. As described above, the expected physical metric value and the expected heat map value can be derived. It should be noted that although expected physical metric value derivation step S110 is performed first in preparation step S10 in the flowchart illustrated in FIG. 8, the processing order of expected physical metric value derivation step S110 is not limited to this example. It is sufficient if expected physical metric value derivation step S110 is performed prior to training step S160.

Next, as illustrated in FIG. 8, syntax analysis of the training hardware description is performed using parser 26 (training syntax analysis step S130).

Next, the training hardware description is converted into a training graph object in a CDFG format (training conversion step S140).

Next, the training graph object is inputted into a neural network represented by a GAT method (training data input step S150). The training graph object includes a plurality of nodes and one or more edges that have been converted from one or more statements in the training hardware description. The plurality of nodes include one or more first nodes in each of which description position information that indicates a position in the training hardware description is embedded. Each of the one or more first nodes is related to, among the one or more statements in the training hardware description, one or more statements indicated by the description position information. The neural network represented by the GAT method includes, as one or more weights, one or more attention coefficients each of which indicates a degree of influence that a different one of the one or more edges of the training graph object has on an inferred physical metric. In training data input step S150, together with the training graph object, a constraint condition of the training semiconductor integrated circuit, library information including, for example, structure information on the constituent elements included in the training semiconductor integrated circuit, or the like may be inputted into the neural network.

Next, the neural network is trained by using the training graph object as an input and the expected physical metric value as training data (training step S160). Next, when there is another training graph object, the process returns to expected physical metric value derivation step S110 and the above-described steps are repeated. Thus, the neural network that has been trained is prepared. It should be noted that although preparation step S10 is performed first in the flowchart illustrated in FIG. 7, the processing order of preparation step S10 is not limited to this example. It is sufficient if preparation step S10 is performed prior to inference step S50.

Next, as illustrated in FIG. 7, syntax analysis of a hardware description is performed (syntax analysis step S20).

Next, the hardware description is converted into a graph object in a CDFG format (conversion step S30).

Next, the graph object obtained at conversion step S30 is inputted into the neural network that has been trained and is represented by the GAT method (data input step S40). In data input step S40, together with the graph object, a constraint condition of a semiconductor integrated circuit, library information including, for example, structure information on the constituent elements included in the semiconductor integrated circuit, or the like may be inputted into the neural network that has been trained.

Next, an inferred physical metric of the semiconductor integrated circuit is inferred by the neural network that has been trained (inference step S50).

Next, an attention part of the hardware description is extracted based on the inferred physical metric (extraction step S60). In extraction step S60, based on one or more attention coefficients each of which indicates a degree of influence on the inferred physical metric, one or more first edges are identified from among one or more edges, and a part of the hardware description is extracted as an attention part based on the description position information of each of one or more first nodes corresponding to the one or more first edges. In the present embodiment, a heat map that is a hardware description indicating a statement having a high degree of importance in the hardware description is generated.

As described above, since an attention part having a high degree of influence on a physical metric in a hardware description can be estimated in the semiconductor integrated circuit design assistance method according to the present embodiment, an inferred physical metric can be improved by revising the attention part when the inferred physical metric should be revised.

### [4. Advantageous Effects, etc.]

A semiconductor integrated circuit design assistance method according to the present embodiment and an effect thereof will be described.

A semiconductor integrated circuit design assistance method according to a first aspect of the present embodiment includes: conversion step S30 of converting, into a graph object in a CDFG format, a hardware description in which a semiconductor integrated circuit is described in a hardware description language; inference step S50 of inferring an inferred physical metric of the semiconductor integrated circuit by inputting the graph object into a neural network that has been trained and is represented by a GAT method; and extraction step S60 of extracting an attention part of the hardware description based on the inferred physical metric. In the semiconductor integrated circuit design assistance method, the graph object includes a plurality of nodes and one or more edges that have been converted from one or more statements in the hardware description, the plurality of nodes include one or more first nodes in each of which description position information that indicates a position in the hardware description is embedded, each of the one or more first nodes is related to, among the one or more statements in the hardware description, one or more statements that are indicated by the description position information of the first node, the neural network includes, as one or more weights, one or more attention coefficients each of which indicates a degree of influence that a different one of the one or more edges has on the inferred physical metric, and in the extracting, one or more first edges are identified from among the one or more edges based on the one or more attention coefficients and a part of the hardware description is extracted as the attention part based on the description position information of, among the one or more first nodes, each pair of first nodes that corresponds to a different one of the one or more first edges.

Accordingly, a physical metric of a semiconductor integrated circuit can be estimated with high accuracy by performing inference using a neural network that has been trained and is represented by a GAT method. Moreover, in the present embodiment, an attention part in a hardware description can be extracted based on description position information embedded in a node connected to an edge having a high attention coefficient in a graph object. Accordingly, a description position, in a hardware description, of a statement having a big influence on a physical metric can be identified. Thus, since a physical metric of a semiconductor integrated circuit and an attention part having a big influence on the physical metric in a hardware description can be estimated based on the hardware description, the physical metric of the semiconductor integrated circuit can be improved by revising the hardware description at an initial stage of design of the semiconductor integrated circuit.

A semiconductor integrated circuit design assistance method according to a second aspect of the present embodiment is the semiconductor integrated circuit design assistance method according to the first aspect in which the one or more first nodes include a second node that corresponds to an operator, the description position information of the second node includes a first line number that is a number assigned to a line in which the operator is written in the hardware description, and the second node includes the first line number as a feature.

Accordingly, since an attention part of a hardware description can be extracted based on a line number in the hardware description, a part that should be revised in the hardware description can be easily identified.

A semiconductor integrated circuit design assistance method according to a third aspect of the present embodiment is the semiconductor integrated circuit design assistance method according to the second aspect in which the one or more first edges include a second edge that is connected to the second node, and the second edge includes the first line number as a feature.

Accordingly, since an attention coefficient that is a weight for a second edge and a line number in a hardware description can be associated with each other, an attention part in the hardware description can be easily extracted.

A semiconductor integrated circuit design assistance method according to a fourth aspect of the present embodiment is the semiconductor integrated circuit design assistance method according to the second aspect or the third aspect in which the second node includes, as a feature, a second line number that is a number assigned to a line in which a variable that is referred to by the operator is defined in the hardware description.

Accordingly, a number assigned to a line in which a variable that is referred to by an operator is written in a hardware description can be easily extracted.

A semiconductor integrated circuit design assistance method according to a fifth aspect of the present embodiment is the semiconductor integrated circuit design assistance method according to any one of the first to fourth aspects in which each of the plurality of nodes corresponds to any of one or more hardware instances that achieve a function described in the hardware description, and each of the one or more edges corresponds to any of one or more connection parts connected to the one or more hardware instances.

A semiconductor integrated circuit design assistance method according to a sixth aspect of the present embodiment is the semiconductor integrated circuit design assistance method according to the fifth aspect in which each of the one or more first nodes includes, as a feature, a degree of computational complexity in, among the one or more hardware instances, one or more hardware instances corresponding to one or more statements in the hardware description indicated by the description position information.

Thus, learning based on more information is made possible by embedding, as a feature, into a neural network, a degree of computational complexity that is an indicator related to a physical metric of a semiconductor integrated circuit. Accordingly, the accuracy of inference by a neural network can be increased.

A semiconductor integrated circuit design assistance method according to a seventh aspect of the present embodiment is the semiconductor integrated circuit design assistance method according to any one of the first to sixth aspects in which each of the one or more first nodes includes, as a feature, a total number of inputs to the first node.

Thus, learning based on more information is made possible by embedding, as a feature, into a neural network, a total number of inputs to a node that is an indicator related to a physical metric of a semiconductor integrated circuit. Accordingly, the accuracy of inference by a neural network can be increased.

A semiconductor integrated circuit design assistance method according to an eighth aspect of the present embodiment is the semiconductor integrated circuit design assistance method according to the fifth aspect in which each of the one or more first edges includes, as a feature, an amount of information transmitted by, among the one or more connection parts, one or more connection parts corresponding to the first edge.

Thus, learning based on more information is made possible by embedding, as a feature, into a neural network, an amount of information transmitted by a connection part that is an indicator related to a physical metric of a semiconductor integrated circuit. Accordingly, the accuracy of inference by a neural network can be increased.

A semiconductor integrated circuit design assistance method according to a ninth aspect of the present embodiment is the semiconductor integrated circuit design assistance method according to the eighth aspect in which the hardware description is written at an RTL, the one or more connection parts corresponding to the one or more first edges are one or more wirings connected to the one or more hardware instances, each of the one or more wirings includes a bus architecture, and the amount of information includes a bus width of the bus architecture.

Thus, learning based on more information is made possible by embedding, as a feature, into a neural network, a bus width of a bus architecture that is an indicator related to a physical metric of a semiconductor integrated circuit. Accordingly, the accuracy of inference by a neural network can be increased.

A semiconductor integrated circuit design assistance method according to a tenth aspect of the present embodiment is the semiconductor integrated circuit design assistance method according to any one of the first to eighth aspects in which the hardware description is written at an RTL.

A semiconductor integrated circuit design assistance method according to an eleventh aspect of the present embodiment is the semiconductor integrated circuit design assistance method according to any one of the first to eighth aspects in which the hardware description is written at a behavioral level.

A semiconductor integrated circuit design assistance method according to a twelfth aspect of the present embodiment is the semiconductor integrated circuit design assistance method according to any one of the first to eighth aspects in which the hardware description is written in a unified modeling language.

A semiconductor integrated circuit design assistance method according to a thirteenth aspect of the present embodiment is the semiconductor integrated circuit design assistance method according to any one of the first to tenth aspects in which each of the one or more first nodes includes, as a feature, a total number of nodes through which an input passes before reaching the first node among the plurality of nodes.

Thus, learning based on more information is made possible by embedding, as a feature, into a neural network, a total number of the above-described nodes that is an indicator related to a physical metric of a semiconductor integrated circuit. Accordingly, the accuracy of inference by a neural network can be increased.

A semiconductor integrated circuit design assistance method according to a fourteenth aspect of the present embodiment is the semiconductor integrated circuit design assistance method according to any one of the first to thirteenth aspect in which the inferred physical metric includes a result of inferring a degree of wire congestion and is inferred as a predicted congestion value included in each of the plurality of nodes, the degree of wire congestion indicating a total number of wires present in a unit region in layout data of the semiconductor integrated circuit, the layout data having been derived based on the hardware description.

Accordingly, a degree of wiring congestion can be improved by revising an attention part of a hardware description based on the degree of wiring congestion.

A semiconductor integrated circuit design assistance method according to a fifteenth aspect of the present embodiment is the semiconductor integrated circuit design assistance method according to any one of the first to fourteenth aspect in which the inferred physical metric includes a result of inferring a power density and is inferred as a predicted power density value included in each of the plurality of nodes, the power density indicating power consumed in a unit region in layout data of the semiconductor integrated circuit, the layout data having been derived based on the hardware description.

Accordingly, a power density can be improved by revising an attention part of a hardware description based on the power density.

A semiconductor integrated circuit design assistance method according to a sixteenth aspect of the present embodiment is the semiconductor integrated circuit design assistance method according to any one of the first to fifteenth aspect in which the inferred physical metric includes a result of inferring a signal propagation time in each of a plurality of signal paths included in layout data of the semiconductor integrated circuit, and is inferred as a predicted signal propagation time value of, among the plurality of signal paths, each of one or more signal paths that includes any of the plurality of nodes, the layout data having been derived based on the hardware description.

Accordingly, a critical path that is, among a plurality of signal paths each leading to one node, a signal path through which a signal reaches the one node at a latest timing can be inferred.

A semiconductor integrated circuit design assistance method according to a seventeenth aspect of the present embodiment is the semiconductor integrated circuit design assistance method according to any one of the first to sixteenth aspects that includes: preparation step S10 of preparing the neural network, and preparation step S10 includes: training conversion step S140 of converting, into a training graph object in a CDFG format, a training hardware description in which a training semiconductor integrated circuit is described; logic synthesis step S114 of performing logic synthesis to generate a gate level netlist based on the training hardware description; layout step S116 of generating layout data based on the gate level netlist; derivation step S120 of deriving an expected physical metric value from the layout data; and training step S160 of training the neural network by using the training graph object as an input and the expected physical metric value as training data.

Accordingly, since a neural network can be trained based on highly accurate training data, a neural network that can perform highly accurate inference can be achieved.

### (Variations, etc.)

Although a semiconductor integrated circuit design assistance method according to the present disclosure and the like has been described based on the embodiment, the present disclosure is not limited to the embodiment. Forms obtained by various modifications to the embodiment that can be conceived by a person skilled in the art as well as forms realized by combining some of the constituent elements in the embodiment are included in the scope of the present disclosure as long as they do not depart from the essence of the present disclosure.

Moreover, the following forms may be included in the scope of one or more aspects of the present disclosure.

(1) Some of the constituent elements included in semiconductor integrated circuit design assistance device 10 may be a computer system including a microprocessor, a ROM, a RAM, a hard disk unit, a display unit, a keyboard, a mouse, or the like. A computer program is stored in the RAM or the hard disk unit. The microprocessor operates according to the computer program to achieve its function. Here, the computer program is configured by combining a plurality of instruction codes each of which indicates a command for a computer to achieve a predetermined function.

(2) Some of the constituent elements included in semiconductor integrated circuit design assistance device 10 described above may be configured of a single system Large Scale Integrated (LSI) circuit. The system LSI circuit is a super-multifunction LSI circuit manufactured by integrating a plurality of components on a single chip, and is specifically a computer system configured to include a microprocessor, a ROM, and a RAM, for example. A computer program is stored in the RAM. The microprocessor operates according to the computer program and thus the system LSI circuit achieves its function.

(3) Some of the constituent elements included in semiconductor integrated circuit design assistance device 10 described above may be configured of a single module or an IC card that is detachable to each device. The IC card or the module is a computer system including a microprocessor, a ROM, a RAM, or the like. The IC card or the module may include the above-described super-multifunction LSI circuit. The microprocessor operates according to the computer program and thus the IC card or the module achieves its function. The IC card or the module may be tamperproof.

(4) Moreover, some of the constituent elements included in semiconductor integrated circuit design assistance device 10 described above may be a computer-readable recording medium, such as a flexible disk, a hard disk, a CD-ROM, an MO, a DVD, a DVD-ROM, a DVD-RAM, a Blu-ray (registered trademark) Disc (BD), or a semiconductor memory, that stores the computer program or the digital signal. Moreover, some of the constituent elements included in semiconductor integrated circuit design assistance device 10 described above may be the digital signal stored in the recording medium.

Furthermore, some of the constituent elements included in semiconductor integrated circuit design assistance device 10 described above may transmit the computer program or the digital signal via a telecommunication line, a wireless or wired communication line, a network such as the Internet, a data broadcast, or the like.

(5) The present disclosure may be the method described above. Moreover, the present disclosure may also be a computer program that causes a computer to realize the method, or a digital signal that includes the computer program. Furthermore, the present disclosure may be achieved as a non-transitory computer-readable recording medium, such as a CD-ROM, that stores the computer program.

(6) Moreover, the present disclosure may be a computer system including a microprocessor and a memory, and the memory may store the computer program and the microprocessor may operate according to the computer program.

(7) Moreover, the present disclosure may be achieved by an other independent computer system by transmitting the program or the digital signal stored in the recording medium to the other independent computer or transmitting the program or the digital signal to the other independent computer system via the network or the like.

(8) The above-described embodiment and the variations may be arbitrarily combined.

Although only some exemplary embodiments of the present disclosure have been described in detail above, those skilled in the art will readily appreciate that many modifications are possible in the exemplary embodiments without materially departing from the novel teachings and advantages of the present disclosure.

Accordingly, all such modifications are intended to be included within the scope of the present disclosure.

### INDUSTRIAL APPLICABILITY

In designing of a semiconductor integrated circuit, the present disclosure can be used as a semiconductor integrated circuit design assistance method in which a part that should be revised in a hardware description can be identified with high accuracy at the initial stage of the designing.

1. A semiconductor integrated circuit design assistance method comprising:
converting, into a graph object in a control data flow graph (CDFG) format, a hardware description in which a semiconductor integrated circuit is described in a hardware description language;
inferring an inferred physical metric of the semiconductor integrated circuit by inputting the graph object into a neural network that has been trained and is represented by a graph attention network (GAT) method; and
extracting an attention part of the hardware description based on the inferred physical metric, wherein
the graph object includes a plurality of nodes and one or more edges, the plurality of nodes and the one or more edges having been converted from one or more statements in the hardware description,
the plurality of nodes include one or more first nodes in each of which description position information that indicates a position in the hardware description is embedded,
each of the one or more first nodes is related to, among the one or more statements in the hardware description, one or more statements that are indicated by the description position information of the first node,
the neural network includes, as one or more weights, one or more attention coefficients each of which indicates a degree of influence that a different one of the one or more edges has on the inferred physical metric, and
in the extracting, one or more first edges are identified from among the one or more edges based on the one or more attention coefficients, and a part of the hardware description is extracted as the attention part based on the description position information of, among the one or more first nodes, each pair of first nodes that corresponds to a different one of the one or more first edges.

2. The semiconductor integrated circuit design assistance method according to claim 1, wherein
the one or more first nodes include a second node that corresponds to an operator,
the description position information of the second node includes a first line number that is a number assigned to a line in which the operator is written in the hardware description, and
the second node includes the first line number as a feature.

3. The semiconductor integrated circuit design assistance method according to claim 2, wherein
the one or more first edges include a second edge that is connected to the second node, and
the second edge includes the first line number as a feature.

4. The semiconductor integrated circuit design assistance method according to claim 2, wherein
the second node includes, as a feature, a second line number that is a number assigned to a line in which a variable that is referred to by the operator is defined in the hardware description.

5. The semiconductor integrated circuit design assistance method according to claim 1, wherein
each of the plurality of nodes corresponds to any of one or more hardware instances that achieve a function described in the hardware description, and
each of the one or more edges corresponds to any of one or more connection parts connected to the one or more hardware instances.

6. The semiconductor integrated circuit design assistance method according to claim 5, wherein
each of the one or more first nodes includes, as a feature, a degree of computational complexity in, among the one or more hardware instances, one or more hardware instances corresponding to one or more statements in the hardware description indicated by the description position information.

7. The semiconductor integrated circuit design assistance method according to claim 1, wherein
each of the one or more first nodes includes, as a feature, a total number of inputs to the first node.

8. The semiconductor integrated circuit design assistance method according to claim 5, wherein
each of the one or more first edges includes, as a feature, an amount of information transmitted by, among the one or more connection parts, one or more connection parts corresponding to the first edge.

9. The semiconductor integrated circuit design assistance method according to claim 8, wherein
the hardware description is written at a register transfer level (RTL),
the one or more connection parts corresponding to the one or more first edges are one or more wirings connected to the one or more hardware instances,
each of the one or more wirings includes a bus architecture, and
the amount of information includes a bus width of the bus architecture.

10. The semiconductor integrated circuit design assistance method according to claim 1, wherein
the hardware description is written at a register transfer level (RTL).

11. The semiconductor integrated circuit design assistance method according to claim 1, wherein
the hardware description is written at a behavioral level.

12. The semiconductor integrated circuit design assistance method according to claim 1, wherein
the hardware description is written in a unified modeling language.

13. The semiconductor integrated circuit design assistance method according to claim 10, wherein
each of the one or more first nodes includes, as a feature, a total number of nodes through which an input passes before reaching the first node among the plurality of nodes.

14. The semiconductor integrated circuit design assistance method according to claim 1, wherein
the inferred physical metric includes a result of inferring a degree of wire congestion and is inferred as a predicted congestion value included in each of the plurality of nodes, the degree of wire congestion indicating a total number of wires present in a unit region in layout data of the semiconductor integrated circuit, the layout data having been derived based on the hardware description.

15. The semiconductor integrated circuit design assistance method according to claim 1, wherein
the inferred physical metric includes a result of inferring a power density and is inferred as a predicted power density value included in each of the plurality of nodes, the power density indicating power consumed in a unit region in layout data of the semiconductor integrated circuit, the layout data having been derived based on the hardware description.

16. The semiconductor integrated circuit design assistance method according to claim 1, wherein
the inferred physical metric includes a result of inferring a signal propagation time in each of a plurality of signal paths included in layout data of the semiconductor integrated circuit, and is inferred as a predicted signal propagation time value of, among the plurality of signal paths, each of one or more signal paths that includes any of the plurality of nodes, the layout data having been derived based on the hardware description.

17. The semiconductor integrated circuit design assistance method according to claim 1, comprising:
preparing the neural network, wherein
the preparing includes:
converting, into a training graph object in a CDFG format, a training hardware description in which a training semiconductor integrated circuit is described;
performing logic synthesis to generate a gate level netlist based on the training hardware description;
generating layout data based on the gate level netlist;
deriving an expected physical metric value from the layout data; and
training the neural network by using the training graph object as an input and the expected physical metric value as training data.
